(19) United States
(12) Patent Application Publication
(10) Pub. No.: US 2004/0074438 A1
(43) Pub. Date: Apr. 22, 2004

(54) Novel method to reduce resistivity of atomic layer tungsten chemical vapor depositon

(75) Inventors: Chii-Ming Wu, Taipei (TW); Shau-Lin Shue, Hsinchu (TW)

Correspondence Address: GEORGE O. SAILE & ASSOCIATES, 28 DAVIS AVENUE, POUGHKEEPSIE, NY, 12603, US

(73) Assignee: Taiwan Semiconductor Manufacturing Company

(21) Appl. No.: 10/278,140

(22) Filed: Oct. 22, 2002

(51) Int. Cl. C30B 23/00; C30B 25/00; C30B 28/12; C30B 28/14

(52) U.S. Cl. 117/104

(57) ABSTRACT

A method of forming a layer of tungsten consisting of separate atomic layers upon a substrate, comprising the following steps. Atomic layers of tungsten are formed upon the substrate by sequentially introducing and purging A, B and C Cycles of gasses. The A Cycle comprising a first gas at a first flow rate for a first time. The B Cycle comprising a second gas at a second flow rate for a second time. The C Cycle comprising the third gas at a third flow rate for a third time. A First Cycle Set comprises an A Cycle and a B Cycle while a Second Cycle Set comprises an A Cycle, a B Cycle and a C Cycle. Whereby a series of First Cycle Sets with a number of Second Cycle Sets at a variable frequency are performed to form the layer of tungsten so that impurities are substantially eliminated within the formed layer of tungsten.

### FIELD OF THE INVENTION

The present invention relates generally to semiconductor fabrication and more specifically to methods of fabricating atomic layer tungsten CVD layers.

### BACKGROUND OF THE INVENTION

Atomic layer tungsten chemical vapor deposition (W-CVD) is a new method for advanced ULSI technology. Theoretically, layer-by-layer growth results in perfect step coverage. It can be used as a nucleation layer of W-CVD and significantly reduce tungsten seam size. However, the reduction gas will induce impurities in the film and so increase resistivity.

In the current atomic layer W-CVD method, alternating sequential flow/purges of two gasses: 1) a reduction gas that may be either SiH₄ (silane) or B₂H₆ (diborane) and 2) WF₆ (source of tungsten (W)). With A=the reduction gas (SiH₄ or B₂H₆) flow/purge and B=WF₆ flow/purge then A-B Cycles (A-B-A-B-AB . . . ) are used to form atomic layer by atomic layer build up of tungsten.

However, each atomic layer includes atom impurities with the desired W atoms, e.g. when using silane (SiH₄) as the reduction gas Si atom impurities are introduced:

W—W—Si—W—Si—W—W—W—W

W—Si—W—W—W—W—Si—W—W

W—W—W—Si—W—W—W—W—W

W—W—Si—W—W—Si—W—Si—W

[where “W” is a tungsten atom and “Si” is a silicon atom] which, as noted above, increases resistivity (R_{C} or contact resistance). Theoretically, the atomic layer W-CVD should form pure tungsten (W) layers, e.g.:

W—W—W—W—W—W—W—W—W

W—W—W—W—W—W—W—W—W

W—W—W—W—W—W—W—W—W

W—W—W—W—W—W—W—W—W

U.S. Pat. No. 6,139,700 to Kang et al. describes an atomic layer deposition (ALD) method for tungsten.

U.S. Pat. No. 6,107,199 to Allen et al. describes a tungsten deposition method with multiple steps and gas flows.

U.S. Pat. No. 6,046,104 to Kepler describes a tungsten method which stops and starts WF₆ and SiH₆ gas flow.

U.S. Pat. Nos. 5,963,836 to Kang et al., 5,874,360 to Wyborn et al. and 5,795,824 to Hancock describe related tungsten methods.

### SUMMARY OF THE INVENTION

Accordingly, it is an object of one or more embodiments of the present invention to provide an improved method of forming atomic layer tungsten CVD layers.

Other objects will appear hereinafter.

It has now been discovered that the above and other objects of the present invention may be accomplished in the following manner. Specifically, atomic layers of tungsten are formed upon a substrate by sequentially introducing and purging A, B and C Cycles of gasses. The A Cycle comprising a first gas at a first flow rate for a first time. The B Cycle comprising a second gas at a second flow rate for a second time. The C Cycle comprising the second gas at a third flow rate for a third time. A First Cycle Set comprises an A Cycle and a B Cycle while a Second Cycle Set comprises an A Cycle, a B Cycle and a C Cycle. Whereby a series of First Cycle Sets with a number of Second Cycle Sets at a variable frequency are performed to form the layer of tungsten so that impurities are substantially eliminated within the formed layer of tungsten.

### DETAILED DESCRIPTION OF THE PREFERRED EMBODIMENT

Unless otherwise specified, all structures, layers, steps, methods, etc. may be formed or accomplished by conventional steps or methods known in the prior art.

The inventors have discovered a novel atomic layer W-CVD method to form tungsten (W) layers using alternating flow/purge cycles of an SiH₄ (silane) reduction gas (A Cycle) and WF₆ (B Cycle) whereby instead of alternating just A-B Cycles repeatedly, an additional C Cycle consisting of another flow/purge of WF₆ is incorporated into the atomic layer W-CVD method at a specific, but variable frequency. For example: A-B/A-B/A-B-C/A-B . . .

The inventors have discovered that this novel cycling improves the tungsten (W) deposit by eliminating impurities in the lattice structure, i.e. to achieve a formed W layer having less than about 1% Si impurities. The C Cycle flow rate and time of flow/purge WF₆ may be different than the B Cycle flow rate and time of flow/purge WF₆.

The time parameters for the A, B and C Cycles are each about 0.001 to 10 seconds. The specific flow rates used may be varied depending upon the size of the reaction chamber used.

The atomic layer W-CVD method is preferably conducted at a wafer temperature of preferably from about 250 to 450° C., more preferably from about 300 to 400° C. and most preferably about 350° C. which is a lower temperature than the conventional W-CVD (A-B Cycle) method; and at a pressure of preferably from about 2.0 to 30.5 Torr and more preferably from about 4.0 to 10.0 Torr which is a lower pressure than the conventional W-CVD (A-B Cycle) method (see below). The W layer so formed is formed at a deposition rate of about 0.5 Å/second and has a resistivity of about 20 μm-cm.

A total of at least about 10 cycles (A, B and C) may be used to fabricate the W layer formed by the atomic layer W-CVD method of the present invention, for example, which may be varied according to the desired thickness of the final tungsten (W) layer to be formed. Within the total number of cycles, ratio of A-B-C Cycles:A-B Cycles is preferably from about 1:1 to 1:8, more preferably from about 1:2 to 1:6 and most preferably from about 1:3 to 1:5. The C Cycle may have a different flow rate or flow time than the B Cycle.

Below are sample portions of such cycles:

I. A-B-A-B-A-B-C-A-B-A-B-A-B-C- . . . ; or

II. A-B-A-B-A-B-A-B-C-A-B-A-B-A-B-A-B-C- . . .

The number of A-B cycles between the A-B-C cycles may be varied.

A barrier layer, such as titanium nitride (TiN), is preferably formed over the patterned layer, such as a patterned dielectric layer, over which a tungsten layer is to be formed to form, for example a W plug or a W line. A tungsten nucleation layer is required to be formed in accordance with the method of the present invention before forming a bulk tungsten layer because hydrogen (H₂) is used as a reduction gas after the nucleation step so the best step coverage may be obtained.

To form the W nucleation layer in accordance with the present invention, a first A Cycle, silane (SiH₄) is introduced into the reaction chamber and purged to cause one atomic layer of SiH₄ to chemisorb to the surface of the TiN barrier layer.

WF₆ in a first B Cycle is introduced into the reaction chamber and purged whereby the WF₆ and SiH₄ react to form by-products (WH₆ and SiF₄) and causing the deposition of a first atomic W layer on the surface of the TiN barrier layer, displacing the chemisorbed SiH₄.

Additional A-B Cycles with a variable number of A-B-C Cycles as explained above, to form additional atomic W layers and to complete formation of the W-nucleation layer.

While particular embodiments of the present invention have been illustrated and described, it is not intended to limit the invention, except as defined by the following claims.

We claim:

1. A method of forming a layer of tungsten consisting of separate atomic layers upon a substrate, comprising the steps of:
forming atomic layers of tungsten upon the substrate by sequentially introducing and purging A, B and C Cycles of gasses;
the A Cycle comprising a first gas at a first flow rate for a first time;
the B Cycle comprising a second gas at a second flow rate for a second time;
the C Cycle comprising the second gas at a third flow rate for a third time;
a First Cycle Set comprising an A Cycle and a B Cycle;
a Second Cycle Set comprising an A Cycle, a B Cycle and a C Cycle;
whereby a series of First Cycle Sets with a number of Second Cycle Sets at a variable frequency are performed to form the layer of tungsten.

2. The method of claim 1, wherein the first, second and third times are each from about 0.001 to 10 seconds.

3. The method of claim 1, wherein the first gas is SiH₄ or B₂H₆ and the second gas is WF₆.

4. The method of claim 1, wherein the first gas is SiH₄ and the second gas is WF,.

5. The method of claim 1, wherein the introduction and purging A, B and C Cycles of gasses are conducted at a substrate temperature of from about 250 to 450° C.

6. The method of claim 1, wherein the introduction and purging A, B and C Cycles of gasses are conducted at a substrate temperature of from about 300 to 400° C.

7. The method of claim 1, wherein the introduction and purging A, B and C Cycles of gasses are conducted at a substrate temperature of about 350° C.

8. The method of claim 1, wherein the introduction and purging A, B and C Cycles of gasses are conducted at a pressure of from about 2.0 to 30.5 Torr.

9. The method of claim 1, wherein the introduction and purging A, B and C Cycles of gasses are conducted at a pressure of from about 4.0 to 10.0 Torr.

10. The method of claim 1, wherein the ratio of Second Cycle Sets First Cycle Sets is from about 1:1 to 1:8.

11. The method of claim 1, wherein the ratio of Second Cycle Sets: First Cycle Sets is from about 1:2 to 1:6.

12. The method of claim 1, wherein the ratio of Second Cycle Sets: First Cycle Sets is from about 1:3 to 1:5.

13. The method of claim 1, wherein the tungsten layer is formed at a deposition rate of about 0.5 Å/second.

14. The method of claim 1, wherein the resistivity of the formed tungsten layer is about 20 μm-cm.

15. The method of claim 1, wherein impurities are substantially eliminated within the formed layer of tungsten.

16. A method of forming a layer of tungsten consisting of separate atomic layers upon a substrate, comprising the steps of:
forming atomic layers of tungsten upon the substrate by sequentially introducing and purging A, B and C Cycles of gasses;
the A Cycle comprising a SiH₄ gas or a B₂H₆ gas at a first flow rate for a first time;
the B Cycle comprising WF₆ gas at a second flow rate for a second time;
the C Cycle comprising WF₆ gas at a third flow rate for a third time;
a First Cycle Set comprises an A Cycle and a B Cycle;
a Second Cycle Set comprises an A Cycle, a B Cycle and a C Cycle comprises;
whereby a series of First Cycle Sets with a number of Second Cycle Sets at a variable frequency are performed to form the layer of tungsten.

17. The method of claim 16, wherein the first, second and third times are each from about 0.001 to 10 seconds.

18. The method of claim 16, wherein the introduction and purging A, B and C Cycles of gasses are conducted at a substrate temperature of from about 250 to 450° C.

19. The method of claim 16, wherein the introduction and purging A, B and C Cycles of gasses are conducted at a substrate temperature of from about 300 to 400° C.

20. The method of claim 16, wherein the introduction and purging A, B and C Cycles of gasses are conducted at a substrate temperature of about 350° C.

21. The method of claim 16, wherein the introduction and purging A, B and C Cycles of gasses are conducted at a pressure of from about 2.0 to 30.5 Torr.

22. The method of claim 16, wherein the introduction and purging A, B and C Cycles of gasses are conducted at a pressure of from about 4.0 to 10.0 Torr.

23. The method of claim 16, wherein the ratio of Second Cycle Sets: First Cycle Sets is from about 1:1 to 1:8.

24. The method of claim 16, wherein the ratio of Second Cycle Sets: First Cycle Sets is from about 1:2 to 1:6.

25. The method of claim 16, wherein the ratio of Second Cycle Sets: First Cycle Sets is from about 1:3 to 1:5.

26. The method of claim 16, wherein the tungsten layer is formed at a deposition rate of about 0.5 Å/second.

27. The method of claim 16, wherein the resistivity of the formed tungsten layer is about 20 μm-cm.

28. The method of claim 16, wherein the A Cycle comprises a SiH₄ gas.

29. The method of claim 16, wherein the A Cycle comprises a B₂H₆ gas.

30. The method of claim 16, wherein impurities comprise about 1% of the formed layer of tungsten.
